(19) United States
(12) Patent Application Publication
(10) Pub. No.: US 2024/0349470 A1
(43) Pub. Date: Oct. 17, 2024

(54) ELECTROMAGNETIC SHIELD AND COMMUNICATIONS UNIT

(71) Applicant: Panasonic Intellectual Property Management Co., Ltd., Osaka (JP)

(72) Inventors: Katsunobu SUZUKI, Kyoto (JP); Eiji OKUZONO, Fukuoka (JP); Masanori MINAMIYAMA, Osaka (JP); Yu OGASAWARA, Kyoto (JP)

(21) Appl. No.: 18/293,668

(22) PCT Filed: Jul. 29, 2022
(86) PCT No.: PCT/JP2022/029246

§ 371 Date: Jan. 30, 2024

(30) Foreign Application Priority Data
Aug. 5, 2021 (JP) 2021-129206

(51) Int. Cl. H05K 9/00

(52) U.S. Cl. CPC H05K 9/009; H05K 9/0049; H05K 9/0086

(57) ABSTRACT

An electromagnetic shield includes a metal sheet, a first viscoelastic layer, and a second viscoelastic layer. The metal sheet has a first surface and a second surface opposite from the first surface. The first viscoelastic layer is provided for the first surface. The second viscoelastic layer is provided for the second surface.

### TECHNICAL FIELD

The present disclosure generally relates to an electromagnetic shield and a communications unit. More particularly, the present disclosure relates to an electromagnetic shield including a metal sheet and a communications unit including such an electromagnetic shield.

### BACKGROUND ART

Patent Literature 1 discloses a laminate including an electromagnetic shield member in which multiple sheets of metal foil are stacked one on top of another to be integrated together. The laminate is characterized by providing, as an integral member, a shock absorber made of an elastomer on the outer surface of at least one of two sheets of metal foil that form the outermost layers of the electromagnetic shield member.

According to the subject-matter of Patent Literature 1, a structure for attaching the laminate onto a target member needs to be provided separately from the laminate. It depends on the structure whether the laminate may be attached easily or not.

### CITATION LIST

### Patent Literature

Patent Literature 1: JP 2013-145778 A

### SUMMARY OF INVENTION

An object of the present disclosure is to provide an electromagnetic shield suitable to be attached onto a member and a communications unit including such an electromagnetic shield.

An electromagnetic shield according to an aspect of the present disclosure includes a metal sheet, a first viscoelastic layer, and a second viscoelastic layer. The metal sheet has a first surface and a second surface opposite from the first surface. The first viscoelastic layer is provided for the first surface. The second viscoelastic layer is provided for the second surface.

A communications unit according to another aspect of the present disclosure includes the electromagnetic shield described above and a communications device. The communications device includes a housing, a terminal block, and a communications module. The housing is to be adhered onto the first viscoelastic layer. The terminal block is held by the housing and allows a cable to be connected to the terminal block itself. The communications module is held by the housing and wirelessly outputs data that the communications module has received via the cable.

### BRIEF DESCRIPTION OF DRAWINGS

FIG. 1 is an exploded perspective view of a communications unit according to an exemplary embodiment;

FIG. 2 is a cross-sectional view illustrating a main part of the communications unit;

FIG. 3 illustrates an exemplary use of the communications unit:

FIG. 4 is an exploded perspective view of an electromagnetic shield of the communications unit;

FIG. 5 is an exploded perspective view of a communications device of the communications unit;

FIG. 6 is a cross-sectional view illustrating a main part of a communications unit according to an implementation of a first variation;

FIG. 7 is a cross-sectional view illustrating a main part of a communications unit according to another implementation of the first variation;

FIG. 8 is a plan view of a first viscoelastic layer according to an implementation of a fourth variation;

FIG. 9 is a plan view of a first viscoelastic layer according to another implementation of the fourth variation;

FIG. 10 is a plan view of a first viscoelastic layer according to still another implementation of the fourth variation; and

FIG. 11 is a plan view of a first viscoelastic layer according to yet another implementation of the fourth variation.

### DESCRIPTION OF EMBODIMENTS

An electromagnetic shield and communications unit according to an exemplary embodiment will now be described with reference to the accompanying drawings. Note that the exemplary embodiment to be described below is only an exemplary one of various embodiments of the present disclosure and should not be construed as limiting. Rather, the exemplary embodiment may be readily modified in various manners depending on a design choice or any other factor without departing from the scope of the present disclosure. The drawings to be referred to in the following description of embodiments are all schematic representations. Thus, the ratio of the dimensions (including thicknesses) of respective constituent elements illustrated on the drawings does not always reflect their actual dimensional ratio.

### Overview

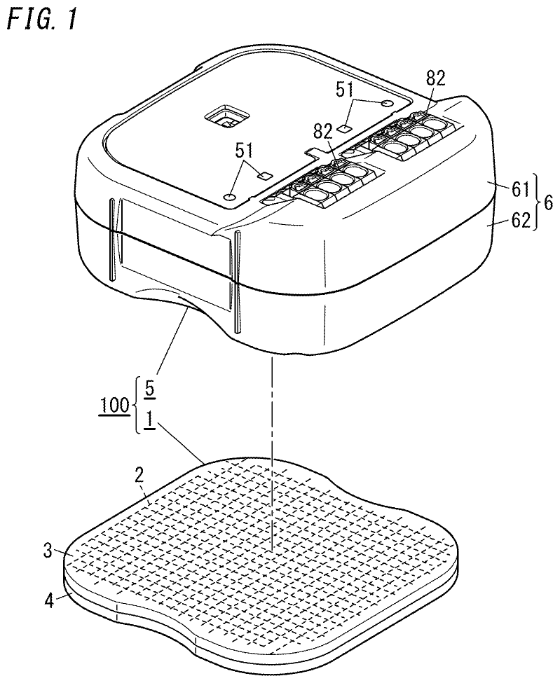

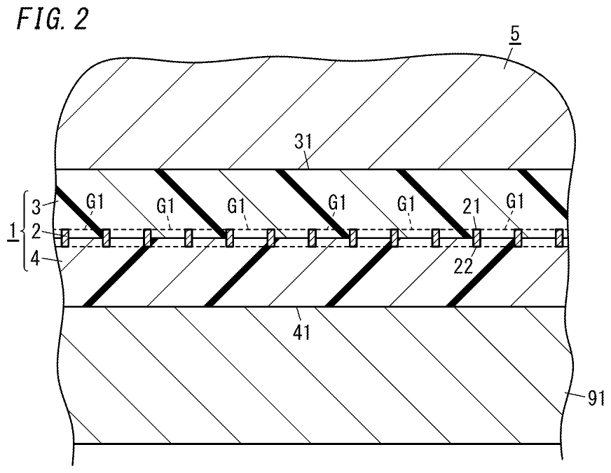

As shown in FIGS. 1 and 2, an electromagnetic shield 1 according to an exemplary embodiment includes a metal sheet 2, a first viscoelastic layer 3, and a second viscoelastic layer 4. The metal sheet 2 has a first surface 21 and a second surface 22 opposite from the first surface 21. The first viscoelastic layer 3 is provided for the first surface 21. The second viscoelastic layer 4 is provided for the second surface 22.

According to this embodiment, the first viscoelastic layer 3 and the second viscoelastic layer 4 provided for both surfaces of the metal sheet 2 have viscosity, thus allowing the metal sheet 2 to be attached onto another member via the first viscoelastic layer 3 and the second viscoelastic layer 4.

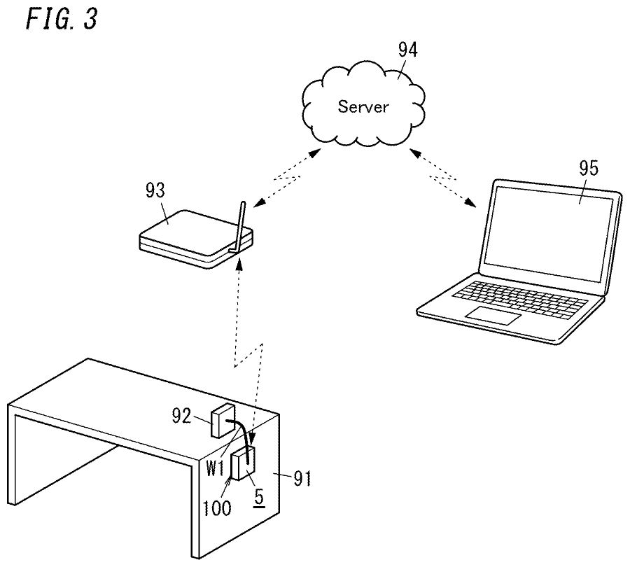

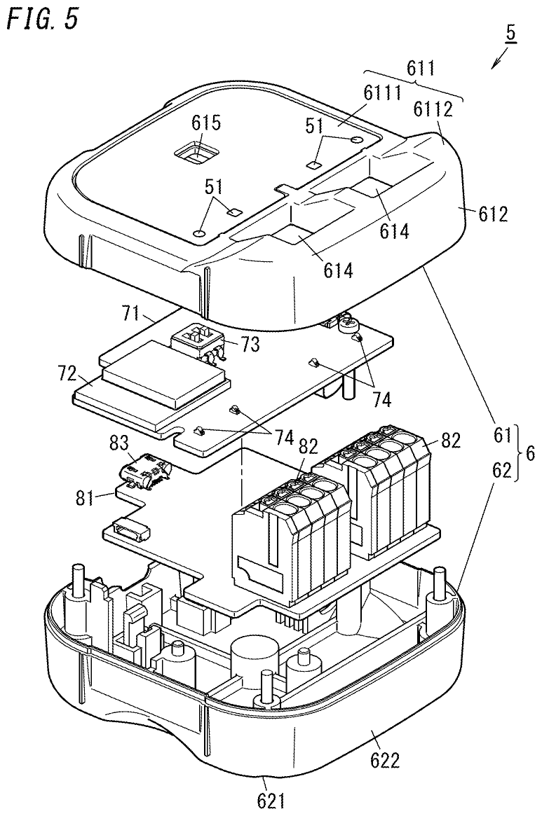

A communications unit 100 according to this embodiment includes the electromagnetic shield 1 and a communications device 5. The communications device 5 includes a housing 6, terminal blocks 82, 83 (refer to FIG. 5), and a communications module 72 (refer to FIG. 5). The housing 6 is to be adhered onto the first viscoelastic layer 3. The terminal blocks 82, 83 are held by the housing 6. A cable W1 (refer to FIG. 3) is connected to each of the terminal blocks 82, 83. The communications module 72 is held by the housing 6 and wirelessly outputs data that the communications module 72 has received via the cable W1.

The electromagnetic shield 1 is interposed between a supporting member 91 (refer to FIGS. 2 and 3) such as a wall, a ceiling, a desk, a workbench, a housing of a machine, or a prop and the communications device 5. In other words, the communications device 5 is mounted onto the supporting member 91 via the electromagnetic shield 1.

The first viscoelastic layer 3 is adhered onto the communications device 5. That is to say, the metal sheet 2 is attached onto the communications device 5 via the first viscoelastic layer 3. This allows electromagnetic noise to be cut off around the communications device 5. In addition, this allows the metal sheet 2 to be disposed close enough to the communications device 5 to improve the communication quality of the communications device 5 significantly. For example, this reduces the chances of radio wave transmission and reception sensitivity becoming relatively low in a particular direction.

The second viscoelastic layer 4 is adhered onto the supporting member 91. That is to say, the metal sheet 2 is attached onto the supporting member 91 via the second viscoelastic layer 4.

In this case, the first viscoelastic layer 3 and the second viscoelastic layer 4 both have viscosity, and therefore, are deformable. For example, the first viscoelastic layer 3 and the second viscoelastic layer 4 are deformable to conform to the surface shape of a target member such as the communications device 5 and the supporting member 91. This makes it easier to attach the electromagnetic shield 1. This allows the electromagnetic shield 1 to be attached onto not only a flat surface but also any one of a curved surface, a surface with unevenness, or a rough surface as well, for example. In addition, this allows the worker to easily attach the electromagnetic shield 1 onto the target member even without using any other member.

Furthermore, the first viscoelastic layer 3 and the second viscoelastic layer 4 have not only viscosity but also elasticity as well, and therefore, may absorb vibration. That is to say, even if the supporting member 91 vibrates, the vibration to be transmitted to the communications device 5 is absorbed into the first viscoelastic layer 3 and the second viscoelastic layer 4 to attenuate into relatively weak vibration. This enables increasing the vibration resistance of the communications device 5.

As can be seen, the electromagnetic shield 1 according to this embodiment has such properties that make the electromagnetic shield 1 suitable to be attached onto a member.

The first viscoelastic layer 3 and the second viscoelastic layer 4 preferably have a hardness of approximately ( ) degrees. For example, at least one of the first viscoelastic layer 3 or the second viscoelastic layer 4 preferably has a hardness equal to or greater than 0 degrees and equal to or less than 5 degrees. The hardness may be measured by Type C testing method defined by the JIS K7312: 1996 standard called “Physical Testing Methods for Molded Products of Thermosetting Polyurethane Elastomers.”

The communications device 5 may be, for example, a wireless terminal or a gateway.

Note that the supporting member 91 does not have to be any particular member. In addition, the target member to be mounted onto the first viscoelastic layer 3 of the electromagnetic shield 1 does not have to be the communications device 5 but may also be any type of device. For example, the target member to be mounted onto the first viscoelastic layer 3 may also be a measuring instrument for measuring a predetermined physical quantity or an image capture device such as a dashcam (corresponding to what is called “drive recorder” in Japan). Meanwhile, the supporting member 91 as the target member to be mounted onto the second viscoelastic layer 4 may also be a moving vehicle such as an automobile or a cart. Furthermore, the material for the supporting member 91 is not limited to any particular one but may also be metal, resin, or wood, for example.

### Details

### (1) Configuration for Electromagnetic Shield

Next, a configuration for the electromagnetic shield 1 will be described in further detail with reference to FIGS. 1, 2, and 4.

The metal sheet 2 is formed in a rectangular shape as a whole. As used herein, the “rectangular” shape refers to a parallelogram having four right angles such as a rectangle and a square. The metal sheet 2 has a first surface 21 and a second surface 22.

The metal sheet 2 has a plurality of gaps G1 (reticulations). This increases the resistance of the metal sheet 2 to the force applied to pull, compress, or bend the whole electromagnetic shield 1 including the metal sheet 2. Providing such a metal sheet 2 for the electromagnetic shield 1 may increase the flexibility of the electromagnetic shield 1. That is to say, this reduces the chances of causing, for example, delamination fracture or cracks to the metal sheet 2 when force is applied to the electromagnetic shield 1.

The metal sheet 2 is formed in the shape of a mesh (reticulations). This enhances the resistance of the metal sheet 2 to the force that causes the metal sheet 2 to stretch and shrink. When viewed in plan, the plurality of gaps G1 each have a rectangular shape. The plurality of gaps G1 are arranged both vertically and horizontally. As used herein, if any constituent element of the electromagnetic shield 1 is “viewed in plan.” this means viewing the constituent element in a thickness direction defined for the metal sheet 2.

When viewed in plan, the plurality of gaps G1 does not have to have a rectangular shape but may also have, for example, a circular, triangular, or regular hexagonal shape as well. Also, the plurality of gaps G1 do not have to be arranged vertically and horizontally but may also be arranged vertically and diagonally, for example.

The metal sheet 2 may contain, as its material, aluminum, copper, or stainless steel, for example.

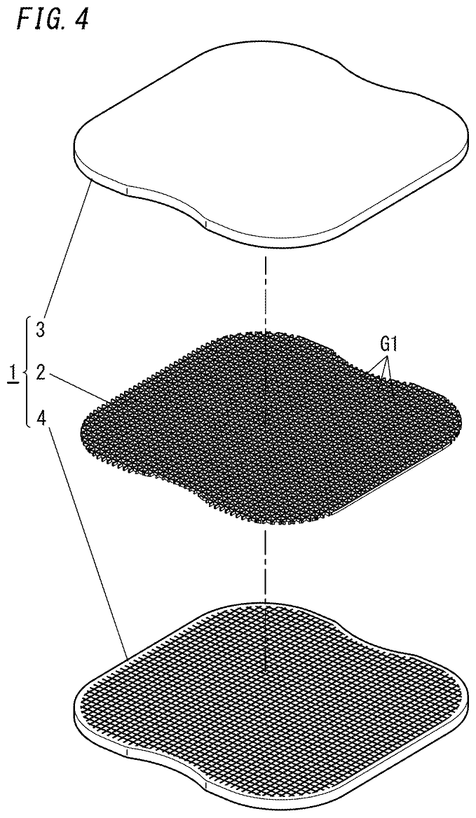

The first viscoelastic layer 3 and the second viscoelastic layer 4 both have a plate shape. When viewed in plan, the first viscoelastic layer 3 and the second viscoelastic layer 4 both have a rectangular shape. Note that the first viscoelastic layer 3, the second viscoelastic layer 4, and the metal sheet 2 are all formed to conform to the shape of the bottom surface of the housing 6 of the communications device 5. Specifically, each of the first viscoelastic layer 3, the second viscoelastic layer 4, and the metal sheet 2 has all four corners thereof rounded and also has two side surfaces thereof recessed when viewed in plan. Note that in FIG. 4, illustrated are meshed grooves, into which the metal sheet 2 is fitted, on the surface of the second viscoelastic layer 4.

The first viscoelastic layer 3 and the second viscoelastic layer 4 both cover the metal sheet 2 entirely. The thickness of the first viscoelastic layer 3 is equal to that of the second viscoelastic layer 4. The planar shape of the first viscoelastic layer 3 is equal to that of the second viscoelastic layer 4. As used herein, if two values are “equal to” each other, then the two values do not have to be exactly equal to each other but may also be different from each other within a practically insubstantial range. For example, if the difference between the two values is less than 5%, then the present disclosure is applicable to such a situation with the two values regarded as being “equal to each other.”

The first viscoelastic layer 3 is provided for the first surface 21 of the metal sheet 2. The second viscoelastic layer 4 is provided for the second surface 22 of the metal sheet 2. That is to say, the metal sheet 2 is sandwiched between the first viscoelastic layer 3 and the second viscoelastic layer 4.

At least one of the first viscoelastic layer 3 or the second viscoelastic layer 4 has its parts embedded in the plurality of gaps G1 of the metal sheet 2. The plurality of gaps G1 are filled with those parts of the at least one viscoelastic layer 3, 4. The first viscoelastic layer 3 and the second viscoelastic layer 4 are bonded together via the plurality of gaps G1. Providing the plurality of gaps G1 may increase the bonding force between the first viscoelastic layer 3 and the second viscoelastic layer 4 compared to a situation where no gaps G1 are provided.

The other surface, opposite from the surface facing the metal sheet 2, of the first viscoelastic layer 3 is a surface to which the communications device 5 is mounted (i.e., adhesive surface 31). The other surface, opposite from the surface facing the metal sheet 2, of the second viscoelastic layer 4 is a surface to be attached to the supporting member 91 (i.e., adhesive surface 41).

At least one of the first viscoelastic layer 3 or the second viscoelastic layer 4 preferably contains a urethane resin as a material thereof. In this embodiment, the first viscoelastic layer 3 and the second viscoelastic layer 4 both contain a urethane resin as a material thereof.

At least one of the first viscoelastic layer 3 or the second viscoelastic layer 4 is preferably gelatinous. In this embodiment, the first viscoelastic layer 3 and the second viscoelastic layer 4 are both gelatinous.

Alternatively, instead of the urethane resin, a silicone resin may also be used as a material for at least one of the first viscoelastic layer 3 or the second viscoelastic layer 4. That is to say, at least one of the first viscoelastic layer 3 or the second viscoelastic layer 4 may include a silicone resin as a material thereof.

The first viscoelastic layer 3 is attached onto the communications device 5, while the second viscoelastic layer 4 is attached onto the supporting member 91. The rigidity of the first viscoelastic layer 3 is different from that of the second viscoelastic layer 4. Preferably, the second viscoelastic layer 4 has lower rigidity than the first viscoelastic layer 3. This makes it easier to attach the second viscoelastic layer 4 onto the supporting member 91 with any of various shapes. For example, if the supporting member 91 has a curved surface, then the second viscoelastic layer 4 may be attached onto the supporting member 91 by deforming the second viscoelastic layer 4 along the curved surface.

The respective rigidity values of the first viscoelastic layer 3 and the second viscoelastic layer 4 may be adjusted by changing, for example, the amounts of a crosslinking agent and a plasticizer to be added to each of the first viscoelastic layer 3 and the second viscoelastic layer 4 during the manufacturing process of the electromagnetic shield 1.

The adhesive force of the first viscoelastic layer 3 is different from that of the second viscoelastic layer 4. Preferably, the adhesive force of the second viscoelastic layer 4 is less than that of the first viscoelastic layer 3. This allows the worker to remove the communications device 5 from the supporting member 91 easily by canceling the adhesive attachment of the second viscoelastic layer 4 to the supporting member 91. In other words, this allows the worker to remove the communications device 5 from the supporting member 91 by easily peeling the second viscoelastic layer 4 off the supporting member 91. Note that as the method for measuring the adhesive force, the method defined by the JIS Z0237: 2009 (called “Testing Methods for Adhesive Tapes and Adhesive Sheets”) is supposed to be adopted in this example.

Furthermore, the viscosity of the first viscoelastic layer 3 is different from that of the second viscoelastic layer 4. Preferably, the second viscoelastic layer 4 has lower viscosity than the first viscoelastic layer 3. This allows the worker to remove the communications device 5 from the supporting member 91 easily by canceling the adhesive attachment of the second viscoelastic layer 4 onto the supporting member 91. After having been removed, the communications device 5 may be mounted onto another target member and used. As can be seen, using the electromagnetic shield 1 to mount a device such as the communications device 5 allows the installation location of the device to be changed easily.

The respective adhesive forces and viscosities of the first viscoelastic layer 3 and the second viscoelastic layer 4 may be adjusted by, for example, changing the content ratio of a urethane resin to a solvent in each of the first viscoelastic layer 3 and the second viscoelastic layer 4 during the manufacturing process of the electromagnetic shield 1.

Each of the first viscoelastic layer 3 and the second viscoelastic layer 4 may have a thickness of 2 mm, for example. The metal sheet 2 may have a thickness of 0.2 mm, for example.

If foreign particles such as dust and dirt adhere to the surface (i.e., the adhesive surface 31, 41 opposite from the surface facing the metal sheet 2) of the first viscoelastic layer 3 and the second viscoelastic layer 4, then the area of contact with the target member decreases, thus causing a decrease in adhesive force as well. At least one of the first viscoelastic layer 3 or the second viscoelastic layer 4 preferably has such a property that allows the at least one viscoelastic layer 3, 4 to recover its adhesive force by having a surface thereof washed with water and then dried. In this embodiment, both the first viscoelastic layer 3 and the second viscoelastic layer 4 have such a property that allows the viscoelastic layers 3, 4 to recover their adhesive force by having their surface washed with water and then dried. Washing the surface with water allows such foreign particles to be removed from the surface of the first viscoelastic layer 3 and the second viscoelastic layer 4.

Such a property that allows the viscoelastic layer 3, 4 to recover their adhesive force by having the surface washed with water and then dried is exhibited when the first viscoelastic layer 3 and the second viscoelastic layer 4 contain a urethane resin as their material and are formed to be gelatinous. Imparting such a property to the first viscoelastic layer 3 and the second viscoelastic layer 4 allows the electromagnetic shield 1 to be used even in a place where there are a lot of foreign particles such as dust and dirt.

Meanwhile, an adhesive is applied onto a double-sided adhesive tape, for example. The adhesive force of the adhesive allows the tape to adhere to a target member. Such an adhesive may be removed by washing the tape with water. In contrast, the first viscoelastic layer 3 and the second viscoelastic layer 4 are caused to adhere to the target member by the adhesive force of the first viscoelastic layer 3 itself and the adhesive force of the second viscoelastic layer 4 itself. Thus, neither the first viscoelastic layer 3 nor the second viscoelastic layer 4 loses their adhesive force even when washed with water. In addition, the first viscoelastic layer 3 and the second viscoelastic layer 4 have water absorbing properties. The first viscoelastic layer 3 and the second viscoelastic layer 4 are made adherable more easily to the target member by absorbing water.

If foreign particles adhere onto the surface of the first viscoelastic layer 3 or the second viscoelastic layer 4, then the surface may be washed with water to remove the foreign particles and then dried naturally, for example. This allows either the first viscoelastic layer 3 or the second viscoelastic layer 4 to recover its adhesive force and makes the first viscoelastic layer 3 or the second viscoelastic layer 4 attachable onto the target member.

### (2) Method for Manufacturing Electromagnetic Shield

Next, a method for manufacturing the electromagnetic shield 1 will be described.

First, a material for the first viscoelastic layer 3 is poured into a first die for use to mold the first viscoelastic layer 3 and heated. This causes the material for the first viscoelastic layer 3 to be cured to a certain degree.

Next, the metal sheet 2 is laid on top of the cured material for the first viscoelastic layer 3.

Subsequently, a second die for use to mold the second viscoelastic layer 4 is combined with the first die. Then, a material for the second viscoelastic layer 4 is poured into the second die and heated. This causes the materials for the first viscoelastic layer 3 and the second viscoelastic layer 4 to be cured, thereby forming the first viscoelastic layer 3 and the second viscoelastic layer 4. In this case, some parts of at least one of the first viscoelastic layer 3 or the second viscoelastic layer 4 enter the plurality of gaps G1 of the metal sheet 2 (refer to FIG. 2). Then, the electromagnetic shield 1 is unloaded from the die assembly.

The electromagnetic shield 1 may be manufactured by performing these process steps.

### (3) Configuration for Communications Device

Next, a configuration for the communications device 5 will be described with reference to FIGS. 1 and 5.

The communications device 5 includes a housing 6, a plurality of (e.g., five in the example illustrated in FIG. 5) terminal blocks 82, a terminal block 83, and a communications module 72. The communications device 5 further includes a first board 71, a dip switch 73, a plurality of (e.g., four in the example illustrated in FIG. 5) light sources 74, a second board 81, and a plurality of (e.g., four in the example illustrated in FIG. 5) light guide members 51. The communications device 5 receives data from a measuring instrument 92 (refer to FIG. 3), for example, via the plurality of terminal blocks 82 or the terminal block 83. The communications device 5 makes the communications module 72 output the data thus received.

A material for the housing 6 may be synthetic resin, for example. The housing 6 includes a first body 61 and a second body 62. The housing 6 is formed by coupling the first body 61 and the second body 62 to each other. The first body 61 and the second body 62 may be coupled to each other with screws, for example.

In the following description, the second body 62 is supposed to be located downward of the first body 61, and the first body 61 is supposed to be located upward of the second body 62. However, this is only an example and should not be construed as limiting the direction in which the communications device 5 is supposed to be used.

The first body 61 includes a top plate 611 and a sidewall 612. The sidewall 612 protrudes downward from the outer peripheral edge of the top plate 611. The top plate 611 includes a flat plate portion 6111 and a bumper 6112. In top view, the flat plate portion 6111 and the bumper 6112 are adjacent to each other. The bumper 6112 protrudes upward with respect to the flat plate portion 6111 having the shape of a flat plate. The bumper 6112 is formed in the shape of a folded plate (or a bent plate).

The housing 6 includes the bumper 6112. When shock is applied to the housing 6 due to a fall, for example, the bumper 6112 absorbs the shock, thus protecting the constituent elements inside the housing 6. Thus, the bumper 6112 increases the crashworthiness of the communications device 5.

One part, provided with the bumper 6112, of the housing 6 has a plurality of (e.g., two in the example illustrated in FIG. 5) windows 614. On the other hand, another part, provided with the flat plate portion 6111, of the housing 6 has another window 615. In addition, a plurality of light guide members 51 are arranged in that part, provided with the flat plate portion 6111, of the housing 6. A first surface (i.e., upper surface) of the plurality of light guide members 51 is exposed outside the housing 6. On the other hand, a second surface (i.e., lower surface) of the plurality of light guide members 51 is exposed inside the housing 6.

The second body 62 includes a bottom plate 621 and a sidewall 622. The sidewall 622 protrudes upward from the outer peripheral edge of the bottom plate 621. The second body 62 holds the first board 71 and the second board 81. This allows the second body 62 to hold the respective components mounted on the first board 71 and the second board 81.

The first board 71 and the second board 81 are housed in the housing 6. The first board 71 and the second board 81 may be, for example, rigid boards. The first board 71 is disposed over the second board 81. The communications module 72, the dip switch 73, and the plurality of light sources 74 are mounted on the first board 71. The plurality of terminal blocks 82 and the terminal block 83 are mounted on the second board 81. The first board 71 and the second board 81 are electrically connected to each other.

The communications module 72 is a wireless communications module that allows the communications device 5 to communicate wirelessly with another device. Examples of communications protocols for the wireless communication established by the communications device 5 include Wi-Fi® and Bluetooth® Low Energy.

The dip switch 73 is exposed to the outside of the housing 6 through the window 615. The user may change the settings of the communications device 5 (e.g., settings about communication to be established by the communications module 72) by operating the dip switch 73.

Each of the plurality of light sources 74 includes, for example, a light-emitting diode and a lens. The communications device 5 changes the lighting states of the light-emitting diodes according to the status (such as the communication status) of the communications device 5. The plurality of light sources 74 are provided one to one for the plurality of light guide members 51. Each of the plurality of light sources 74 faces a corresponding one of the light guide members 51. The light emitted from each light source 74 emerges out of the housing 6 through its corresponding light guide member 51. Each light guide member 51 may be implemented as, for example, a reflector, a diffuser, a light guide plate, or a combination thereof.

As can be seen, the communications device 5 includes the (plurality of) light sources 74 housed in the housing 6 and the (plurality of) light guide members 51 also housed in the housing 6. The light guide members 51 guide the light emitted from the light sources 74.

The plurality of terminal blocks 82 are exposed to the outside of the housing 6 through the plurality of windows 614. A cable W1 (refer to FIG. 3), for example, may be directly connected to each terminal block 82.

The terminal block 83 is exposed to the outside of the housing 6 through a window provided through the housing 6. A cable W1 (refer to FIG. 3) is connected to each terminal block 83 via a connector, for example.

### (4) Dynamic Model

If the communications device 5 is mounted to the supporting member 91 via a double-sided adhesive tape, of which the mass is so small as to be negligible, then the motion of the communications device 5 may be represented by a one-degree-of freedom vibration system. On the other hand, in the configuration according to this embodiment, the mass of the metal sheet 2 of the electromagnetic shield 1 is not negligible, and therefore, the motion produced between the communications device 5 to be mounted onto the electromagnetic shield 1 and the electromagnetic shield 1 may be represented by a two-degree-of freedom vibration system. That is to say, causing the electromagnetic shield 1 to function just like a vibration absorber may attenuate the amplitude of the resonance to the degree that would not be achieved by the one-degree-of freedom vibration system. Consequently, this enables increasing the vibration resistance of the communications device 5.

### (5) Exemplary Use of Communications Unit

Next, an exemplary use of the communications unit 100 will be described with reference to FIG. 3.

The communications unit 100 may be installed on, for example, a production line at a factory. A measuring instrument 92 and a gateway 93, for example, may be further installed on the production line. The measuring instrument 92 measures the working status of workers, the status of use of jigs, and/or the operating status of machines on the production line. The communications unit 100 is used to output the measuring data acquired by the measuring instrument 92 to an external device. This allows the user to recognize these statuses on the production line and spot any problem with the production line, for example. Examples of the measuring instrument 92 include a light sensor, a pressure sensor, a torque sensor, a magnetic sensor, a proximity switch, a current sensor, and an ultrasonic sensor.

The communications device 5 is mounted via the electromagnetic shield 1 (refer to FIG. 2) onto the supporting member 91 such as a desk. The communications device 5 is connected to another device via the cable W1. In FIG. 3, the communications device 5 is connected to the measuring instrument 92 via the cable W1. The communications device 5 wirelessly outputs the data (i.e., measurement data) that the communications device 5 has received from the measuring instrument 92 via wired communication through the cable W1. The data is transmitted from the communications device 5 to the gateway 93.

The gateway 93 outputs the data to a server 94. The server 94 may be a cloud server, for example. The server 94 processes the data. For example, the server 94 collects the data, transforms the data into statistical data, and outputs the statistical data. For example, the server 94 may make analysis based on the data and output analytic data.

Then, the server 94 transmits output data such as the statistical data and the analytic data to a telecommunications device 95. Examples of the telecommunications device 95 include personal computers and mobile communications devices such as cellphones, smartphones, and tablet computers. The user may view the output data by operating the telecommunications device 95.

### Variations of Embodiment

Next, variations of the exemplary embodiment will be described. The variations to be described below may be adopted as appropriate in combination. In the following description of variations, any constituent element, having the same function as a counterpart of the exemplary embodiment described above, will be designated by the same reference numeral as that counterpart's, and description thereof will be omitted herein.

### (First Variation)

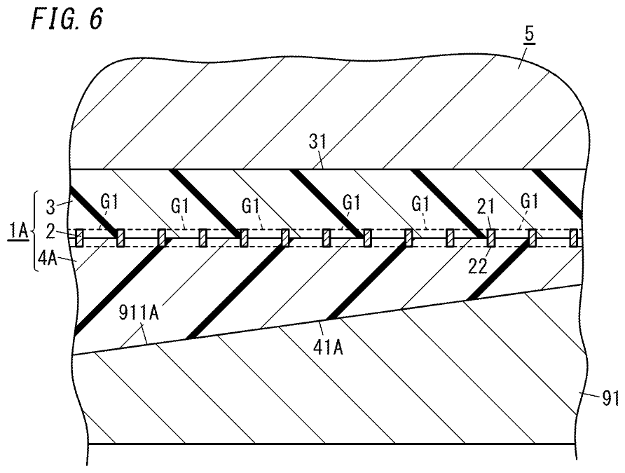

In at least one of the first viscoelastic layer 3 or the second viscoelastic layer 4, the adhesive surface 31, 41 (refer to FIG. 2), opposite from the other surface facing the metal sheet 2, may be formed in a shape that conforms to the shape of the target member, to which the electromagnetic shield 1 is adhered, and that is different from a plane parallel to the metal sheet 2. This configuration makes it easier to mount the electromagnetic shield 1 onto the target member. In this first variation, the adhesive surface 41A of the second viscoelastic layer 4 is formed in such a shape as shown in FIG. 6.

More specifically; in an electromagnetic shield 1A according to an implementation of the first variation, the adhesive surface 41A of the second viscoelastic layer 4A has a tilted surface which is tilted with respect to a plane parallel to the metal sheet 2 as shown in FIG. 6. This allows the communications device 5 to be mounted onto the supporting member 91 via the electromagnetic shield 1A to have the communications device 5 oriented perpendicularly to the ground, even if a surface 911A, to which the electromagnetic shield 1A is to be attached, of the supporting member 91 is not perpendicular to the ground, for example.

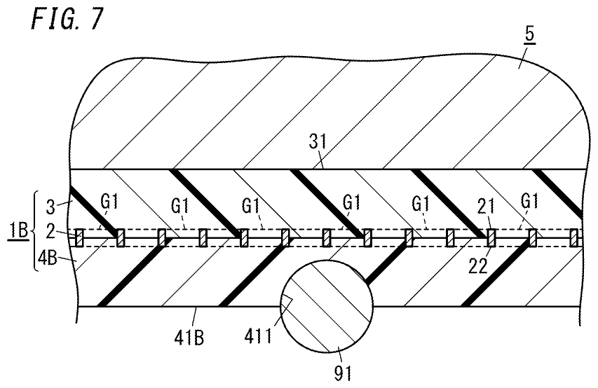

On the other hand, in an electromagnetic shield 1B according to another implementation of the first variation, the adhesive surface 41B of a second viscoelastic layer 4B has a depression 411 as shown in FIG. 7. The depression 411 may have, for example, a spherical shape that conforms to the shape of a ball serving as the supporting member 91. Providing the depression 411 in this manner makes it easier to attach the electromagnetic shield 1B to even a supporting member 91, of which the surface shape is not flat.

### (Second Variation)

The second viscoelastic layer 4 may contain magnetic particles. According to this implementation, when magnetic suction force is produced between the target member (such as the supporting member 91) and the magnetic particles, the magnetic suction force with or without the viscosity allows the electromagnetic shield 1 to be attached onto the target member. This allows, even if the adhesive force produced between the target member and the electromagnetic shield 1 is short of a minimum required level, the electromagnetic shield 1 to be still attached onto the target member.

### (Third Variation)

The color of the first viscoelastic layer 3 may be different from that of the second viscoelastic layer 4. This makes it easier for the worker to distinguish the first viscoelastic layer 3 from the second viscoelastic layer 4. As used herein, the expression “the color is different” refers to, for example, a situation where at least one of the hue, lightness, saturation, or degree of transparency is different. The colors may made different by, for example, adding a pigment to at least one of the first viscoelastic layer 3 or the second viscoelastic layer 4.

### (Fourth Variation)

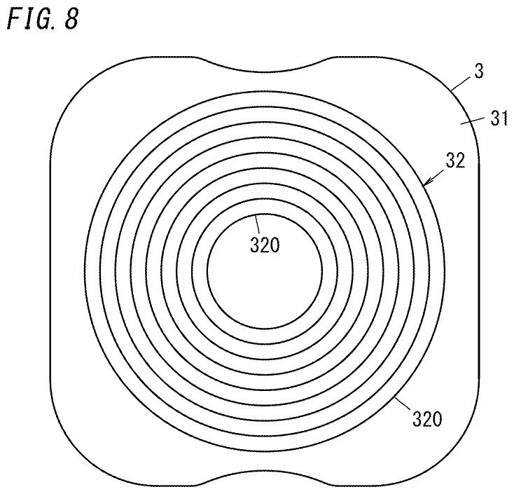

As shown in FIGS. 8-11, a groove 32 may be formed on the adhesive surface 31 of the first viscoelastic layer 3. The groove 32 includes a plurality of stripe portions 320. Each of the plurality of stripe portions 320 is a portion that looks like a stripe (which may be linear or curvilinear) when viewed in plan. The plurality of stripe portions 320 are arranged side by side in a direction different from the direction in which the stripe portions 320 extend. Likewise, a groove may also be formed on the adhesive surface 41 of the second viscoelastic layer 4. That is to say, a groove including a plurality of stripe portions may be formed on the adhesive surface 31, 41, opposite from the other surface facing the metal sheet 2, of at least one of the first viscoelastic layer 3 or the second viscoelastic layer 4. The plurality of stripe portions are arranged side by side in a direction different from the direction in which the stripe portions extend. Although the configuration of the first viscoelastic layer 3 having the groove 32 formed thereon will be described in the following description, the configuration to be described below is applicable to the second viscoelastic layer 4 as well.

FIGS. 8-11 illustrate exemplary shapes of the groove 32. The groove 32 is formed around the center of the adhesive surface 31. The groove 32 spreads isotropically from the center of the adhesive surface 31. The groove 32 may have, for example, a semicircular or polygonal cross-sectional shape.

In FIG. 8, each stripe portion 320 of the groove 32 has a circular shape when viewed in plan. The plurality of stripe portions 320 are arranged concentrically. In addition, the plurality of stripe portions 320 are also arranged at regular intervals. The gap between two adjacent stripe portions 320 may be, for example, equal to or greater than the depth of the stripe portions 320. In the latter case, the gap may be at most twice as large as the depth.

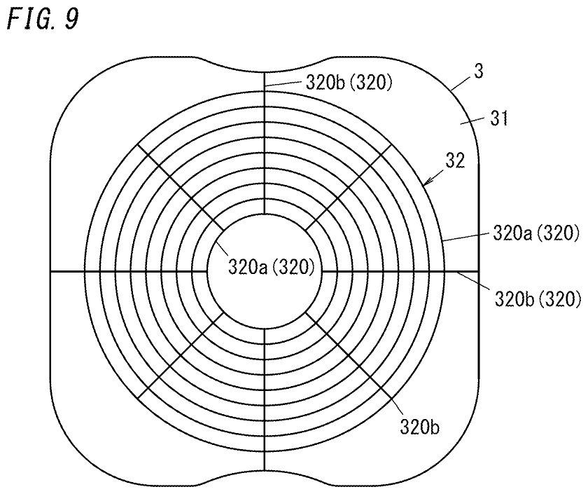

When viewed in plan, the groove 32 shown in FIG. 9 has a shape having not only the plurality of concentrically arranged stripe portions 320a of the groove 32 shown in FIG. 8 but also a plurality of (e.g., eight in the example illustrated in FIG. 9) radially arranged stripe portions 320b as well. The plurality of stripe portions 320b extend outward from the innermost stripe portion 320a along the radius of the stripe portions 320a. The plurality of stripe portions 320b includes stripe portions 320b that extend through the outer edge of the adhesive surface 31.

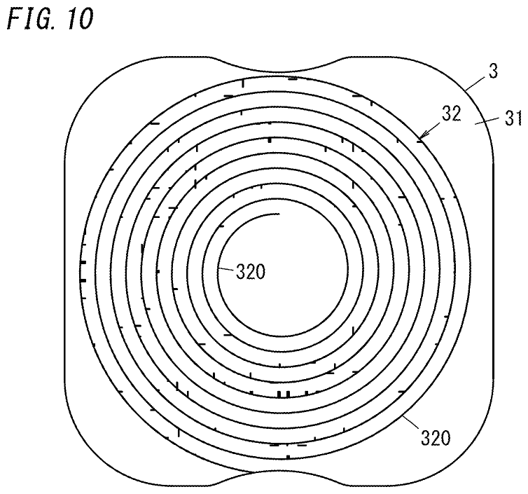

The groove 32 shown in FIG. 10 has a spiral shape when viewed in plan. The groove 32 spirals around the center of the adhesive surface 31. In FIG. 10, the plurality of stripe portions 320) are respectively first-, second- . . . and N^{th}-round parts of the spiral. That is to say, each of the plurality of stripe portions 320 in FIG. 10 is continuous with adjacent stripe portions 320.

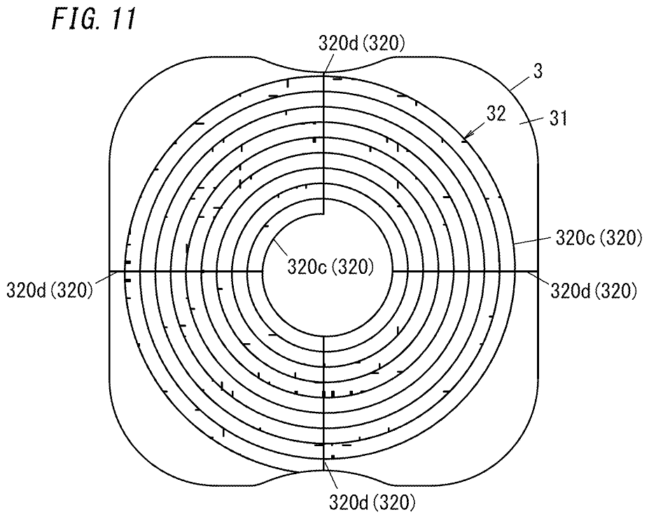

When viewed in plan, the groove 32 shown in FIG. 11 has a shape having not only the plurality of spirally arranged stripe portions 320c shown in FIG. 10 but also a plurality of (e.g., four in the example illustrated in FIG. 11) radially arranged stripe portions 320d as well. The plurality of stripe portions 320d extend outward from the innermost stripe portion 320c. The plurality of stripe portions 320d includes stripe portions 320d that extend through the outer edge of the adhesive surface 31. More specifically, in FIG. 11, all the four stripe portions 320d extend through the outer edge of the adhesive surface 31.

As can be seen from the foregoing description, the first viscoelastic layer 3 according to this fourth variation has the groove 32. The force applied to the first viscoelastic layer 3 when the first viscoelastic layer 3 is attached to a target member such as the communications device 5 may cause the first viscoelastic layer 3 to be deformed. Optionally, the worker may also deform the first viscoelastic layer 3 by applying force intentionally to the first viscoelastic layer 3.

As the first viscoelastic layer 3 is deformed, the groove 32 is partially opened. This allows an oil film layer present on the target member to be peeled off by bringing the oil film layer into contact with an edge portion of the groove 32. In this case, at least part of the oil film layer may move into the groove 32 or be scatter around, whichever is appropriate.

Peeling the oil film layer off may cause an increase in the adhesive force between the first viscoelastic layer 3 and the target member. Thus, this fourth variation allows the electromagnetic shield 1 to be used even in an environment where oil adheres to the target member.

Note that the groove 32 does not have to spread isotropically from the center of the adhesive surface 31. Alternatively, stripe portions 320 having a certain shape may also be arranged, for example, either regularly or irregularly on the adhesive surface 31. Examples of shapes of the stripe portions 320 include circular, elliptical, polygonal, linear, C-, and U-shapes. Still alternatively, the groove 32 may also be formed in a net shape.

Also, although the stripe portions 320 are arranged in FIGS. 8-11 off the center of the adhesive surface 31, the stripe portions 320 may also be provided on the center of the adhesive surface 31.

### Other Variations of Exemplary Embodiment

Next, variations of the exemplary embodiment will be enumerated one after another.

The respective shapes of the metal sheet 2, the first viscoelastic layer 3, the second viscoelastic layer 4, and other members as described for the exemplary embodiment are only examples and should not be construed as limiting. Rather, shapes different from the ones described for the exemplary embodiment may also be adopted as the shapes of these members. For example, the planar shape of the metal sheet 2, the first viscoelastic layer 3, and the second viscoelastic layer 4 may be different from the shape of the bottom surface of the housing 6.

The thickness of the first viscoelastic layer 3 may be different from that of the second viscoelastic layer 4.

The planar shape of the first viscoelastic layer 3 may be different from that of the second viscoelastic layer 4.

When viewed in plan, the first viscoelastic layer 3, the second viscoelastic layer 4, and the metal sheet 2 may have mutually different dimensions.

The plurality of gaps G1 of the metal sheet 2 may be left sparsely. Alternatively, the metal sheet 2 may have no gaps G1.

### (Recapitulation)

The exemplary embodiment and its variations described above are specific implementations of the following aspects of the present disclosure.

An electromagnetic shield (1, 1A, 1B) according to a first aspect includes a metal sheet (2), a first viscoelastic layer (3), and a second viscoelastic layer (4, 4A, 4B). The metal sheet (2) has a first surface (21) and a second surface (22) opposite from the first surface (21). The first viscoelastic layer (3) is provided for the first surface (21). The second viscoelastic layer (4, 4A, 4B) is provided for the second surface (22).

According to this configuration, the first viscoelastic layer (3) and the second viscoelastic layer (4, 4A, 4B) provided for both surfaces of the metal sheet (2) have viscosity, thus allowing the metal sheet (2) to be attached onto a target member via the first viscoelastic layer (3) and the second viscoelastic layer (4, 4A, 4B). For example, attaching the metal sheet (2) onto a device via the first viscoelastic layer (3) allows the metal sheet (2) to be disposed close enough to the device to cut off electromagnetic noise. In addition, attaching the metal sheet (2) onto a supporting member (91) such as a wall, a workbench, or a prop, via the second viscoelastic layer (4, 4A, 4B) allows the device to be mounted onto the supporting member (91) via the electromagnetic shield (1, 1A, 1B). In this case, the first viscoelastic layer (3) and the second viscoelastic layer (4, 4A, 4B) have not only viscosity but also elasticity as well, and therefore, may absorb vibration. This increases the vibration resistance of the device. As can be seen, this configuration enables providing an electromagnetic shield (1, 1A, 1B) suitable to be attached onto a member.

In an electromagnetic shield (1, 1A, 1B) according to a second aspect, which may be implemented in conjunction with the first aspect, the metal sheet (2) has a plurality of gaps (G1).

This configuration may increase the degree of flexibility of the electromagnetic shield (1, 1A, 1B).

In an electromagnetic shield (1, 1A, 1B) according to a third aspect, which may be implemented in conjunction with the second aspect, the metal sheet (2) has a mesh shape.

This configuration may further increase the degree of flexibility of the electromagnetic shield (1, 1A, 1B).

In an electromagnetic shield (1, 1A, 1B) according to a fourth aspect, which may be implemented in conjunction with any one of the first to third aspects, the second viscoelastic layer (4, 4A, 4B) has lower rigidity than the first viscoelastic layer (3).

According to this configuration, a two-degree-of freedom vibration system is formed by a member to be mounted onto the electromagnetic shield (1, 1A, 1B) and the electromagnetic shield (1, 1A, 1B), thus increasing the vibration resistance of the member.

In an electromagnetic shield (1A, 1B) according to a fifth aspect, which may be implemented in conjunction with any one of the first to fourth aspects, at least one of the first viscoelastic layer (3) or the second viscoelastic layer (4A, 4B) has an adhesive surface (31, 41A, 41B) having a shape different from a plane parallel to the metal sheet (2) and conforming to a shape of a target member, to which the at least one of the first viscoelastic layer (3) or the second viscoelastic layer (4A, 4B) is adhered. The adhesive surface (31, 41A, 41B) is opposite from another surface, facing the metal sheet (2), of the at least one of the first viscoelastic layer (3) or the second viscoelastic layer (4A, 4B).

This configuration makes it easier to attach the electromagnetic shield (1A, 1B) onto a target member.

In an electromagnetic shield (1A) according to a sixth aspect, which may be implemented in conjunction with any one of the first to fifth aspects, at least one of the first viscoelastic layer (3) or the second viscoelastic layer (4A) has an adhesive surface (31, 41A) including a tilted surface which is tilted with respect to a plane parallel to the metal sheet (2). The adhesive surface (31, 41A) is opposite from another surface, facing the metal sheet (2), of the at least one of the first viscoelastic layer (3) or the second viscoelastic layer (4A).

According to this configuration, when a device is mounted onto the supporting member (91) via the electromagnetic shield (1A), for example, the orientation of the device depends on the tilt of the tilted surface of the electromagnetic shield (1A). This allows the orientation of the device to be adjusted by defining the tilt of the tilted surface.

In an electromagnetic shield (1B) according to a seventh aspect, which may be implemented in conjunction with any one of the first to sixth aspects, at least one of the first viscoelastic layer (3) or the second viscoelastic layer (4B) has an adhesive surface (31, 41B) having a depression (411). The adhesive surface (31, 41B) is opposite from another surface, facing the metal sheet (2), of the at least one of the first viscoelastic layer (3) or the second viscoelastic layer (4B).

This configuration allows the electromagnetic shield (1B) to be attached onto a member with a non-flat surface such as a pole.

In an electromagnetic shield (1, 1A, 1B) according to an eighth aspect, which may be implemented in conjunction with any one of the first to seventh aspects, the second viscoelastic layer (4, 4A, 4B) has lower adhesive force than the first viscoelastic layer (3).

This configuration allows the target member to be removed easily via the second viscoelastic layer (4, 4A, 4B) with the lower adhesive force.

In an electromagnetic shield (1, 1A, 1B) according to a ninth aspect, which may be implemented in conjunction with any one of the first to eighth aspects, the second viscoelastic layer (4, 4A, 4B) has lower viscosity than the first viscoelastic layer (3).

This configuration allows the target member to be removed easily via the second viscoelastic layer (4, 4A, 4B) with the lower viscosity.

In an electromagnetic shield (1, 1A, 1B) according to a tenth aspect, which may be implemented in conjunction with any one of the first to ninth aspects, the second viscoelastic layer (4, 4A, 4B) includes magnetic particles.

According to this configuration, when magnetic suction force is produced between the target member and the magnetic particles, the magnetic suction force with or without the viscosity allows the electromagnetic shield (1, 1A, 1B) to be attached onto the target member.

In an electromagnetic shield (1, 1A, 1B) according to an eleventh aspect, which may be implemented in conjunction with any one of the first to tenth aspects, the first viscoelastic layer (3) has a different color from the second viscoelastic layer (4, 4A, 4B).

This configuration makes it easier for the worker to distinguish the first viscoelastic layer (3) and the second viscoelastic layer (4, 4A, 4B) from each other.

In an electromagnetic shield (1, 1A, 1B) according to a twelfth aspect, which may be implemented in conjunction with any one of the first to eleventh aspects, at least one of the first viscoelastic layer (3) or the second viscoelastic layer (4, 4A, 4B) contains a urethane resin as a material thereof.

This configuration easily makes both the viscosity and elasticity of the viscoelastic layer relatively high.

In an electromagnetic shield (1, 1A, 1B) according to a thirteenth aspect, which may be implemented in conjunction with any one of the first to twelfth aspects, at least one of the first viscoelastic layer (3) or the second viscoelastic layer (4, 4A, 4B) has a hardness equal to or greater than 0 degrees and equal to or less than 5 degrees.

This configuration allows the electromagnetic shield (1, 1A, 1B) to be easily attached onto any one of a curved surface, a surface with unevenness, or a rough surface.

In an electromagnetic shield (1, 1A, 1B) according to a fourteenth aspect, which may be implemented in conjunction with any one of the first to thirteenth aspects, at least one of the first viscoelastic layer (3) or the second viscoelastic layer (4, 4A, 4B) has a property that allows the at least one of the first viscoelastic layer (3) or the second viscoelastic layer (4, 4A, 4B) to recover adhesive force by having an adhesive surface (31, 41, 41A, 41B) thereof washed with water and then dried. The adhesive surface (31, 41, 41A, 41B) is opposite from another surface, facing the metal sheet (2), of the at least one of the first viscoelastic layer (3) or the second viscoelastic layer (4, 4A, 4B).

This configuration allows the electromagnetic shield (1, 1A, 1B) to be used even in a place where there are a lot of foreign particles such as dust and dirt.

In an electromagnetic shield (1, 1A, 1B) according to a fifteenth aspect, which may be implemented in conjunction with any one of the first to fourteenth aspects, at least one of the first viscoelastic layer (3) or the second viscoelastic layer (4, 4A, 4B) is gelatinous.

This configuration makes it easier to attach the electromagnetic shield (1, 1A, 1B) onto the target member.

In an electromagnetic shield (1, 1A, 1B) according to a sixteenth aspect, which may be implemented in conjunction with any one of the first to fifteenth aspects, at least one of the first viscoelastic layer (3) or the second viscoelastic layer (4, 4A, 4B) has an adhesive surface (31, 41, 41A, 41B) having a groove (32) with a plurality of stripe portions (320). The adhesive surface (31, 41, 41A, 41B) is opposite from another surface, facing the metal sheet (2), of the at least one of the first viscoelastic layer (3) or the second viscoelastic layer (4, 4A, 4B). The plurality of stripe portions (320) are arranged side by side in a direction different from a direction in which the plurality of stripe portions (320) extend.

This configuration allows the electromagnetic shield (1, 1A, 1B) to be used even in an environment where oil adheres to the target member.

Note that the constituent elements according to the second to sixteenth aspects are not essential constituent elements for the electromagnetic shield (1, 1A, 1B) but may be omitted as appropriate.

A communications unit (100) according to a seventeenth aspect includes the electromagnetic shield (1, 1A, 1B) according to any one of the first to sixteenth aspects and a communications device (5). The communications device (5) includes a housing (6), a terminal block (82, 83), and a communications module (72). The housing (6) is to be adhered onto the first viscoelastic layer (3). The terminal block (82, 83) is held by the housing (6) and allows a cable (W1) to be connected to the terminal block (82, 83) itself. The communications module (72) is held by the housing (6) and wirelessly outputs data that the communications module (72) has received via the cable (W1).

This configuration allows the communications device (5) to be easily mounted onto a supporting member (91), for example, via the electromagnetic shield (1, 1A, 1B). In addition, interposing the electromagnetic shield (1, 1A, 1B) including the first viscoelastic layer (3) and the second viscoelastic layer (4, 4A, 4B) may increase the vibration resistance of the communications device (5). Furthermore, this configuration allows the metal sheet (2) to be disposed close enough to the communications device (5) to improve the communication quality of the communications device (5).

In a communications unit (100) according to an eighteenth aspect, which may be implemented in conjunction with the seventeenth aspect, the housing (6) includes a bumper (6112).

This configuration may increase the crashworthiness of the communications device (5).

In a communications unit (100) according to a nineteenth aspect, which may be implemented in conjunction with the seventeenth or eighteenth aspect, the communications device (5) further includes a light source (74) and a light guide member (51). The light source (74) is housed in the housing (6). The light guide member (51) is housed in the housing (6) and guides light emitted from the light source (74).

This configuration allows information about, for example, the operating status of the communications device (5) to be displayed by the light emitted from the light source (74).

Note that the constituent elements according to the eighteenth and nineteenth aspects are not essential constituent elements for the communications unit (100) but may be omitted as appropriate.

### REFERENCE SIGNS LIST

1, 1A, 1B Electromagnetic Shield
2 Metal Sheet
3 First Viscoelastic Layer
4 Second Viscoelastic Layer
5 Communications Device
6 Housing
21 First Surface
22 Second Surface
31, 41, 41A, 41B Adhesive Surface
32 Groove
51 Light Guide Member
72 Communications Module
74 Light Source
82, 83 Terminal Block
100 Communications Unit
320 Stripe Portion
6112 Bumper
G1 Gap
W1 Cable

1. An electromagnetic shield comprising:
a metal sheet having a first surface and a second surface opposite from the first surface;
a first viscoelastic layer provided for the first surface; and
a second viscoelastic layer provided for the second surface.

2. The electromagnetic shield of claim 1, wherein
the metal sheet has a plurality of gaps.

3. The electromagnetic shield of claim 2, wherein
the metal sheet has a mesh shape.

4. The electromagnetic shield of claim 1, wherein
the second viscoelastic layer has lower rigidity than the first viscoelastic layer.

5. The electromagnetic shield of claim 1, wherein
at least one of the first viscoelastic layer or the second viscoelastic layer has an adhesive surface having a shape different from a plane parallel to the metal sheet and conforming to a shape of a target member, to which the at least one of the first viscoelastic layer or the second viscoelastic layer is adhered, the adhesive surface being opposite from another surface, facing the metal sheet, of the at least one of the first viscoelastic layer or the second viscoelastic layer.

6. The electromagnetic shield of claim 1, wherein
at least one of the first viscoelastic layer or the second viscoelastic layer has an adhesive surface including a tilted surface tilted with respect to a plane parallel to the metal sheet, the adhesive surface being opposite from another surface, facing the metal sheet, of the at least one of the first viscoelastic layer or the second viscoelastic layer.

7. The electromagnetic shield of claim 1, wherein
at least one of the first viscoelastic layer or the second viscoelastic layer has an adhesive surface having a depression, the adhesive surface being opposite from another surface, facing the metal sheet, of the at least one of the first viscoelastic layer or the second viscoelastic layer.

8. The electromagnetic shield of claim 1, wherein
the second viscoelastic layer has lower adhesive force than the first viscoelastic layer.

9. The electromagnetic shield of claim 1, wherein
the second viscoelastic layer has lower viscosity than the first viscoelastic layer.

10. The electromagnetic shield of claim 1, wherein
the second viscoelastic layer includes magnetic particles.

11. The electromagnetic shield of claim 1, wherein
the first viscoelastic layer has a different color from the second viscoelastic layer.

12. The electromagnetic shield of claim 1, wherein
at least one of the first viscoelastic layer or the second viscoelastic layer contains a urethane resin as a material thereof.

13. The electromagnetic shield of claim 1, wherein
at least one of the first viscoelastic layer or the second viscoelastic layer has a hardness equal to or greater than 0 degrees and equal to or less than 5 degrees.

14. The electromagnetic shield of claim 1, wherein
at least one of the first viscoelastic layer or the second viscoelastic layer has a property that allows the at least one of the first viscoelastic layer or the second viscoelastic layer to recover adhesive force by having an adhesive surface washed with water and then dried, the adhesive surface being opposite from another surface, facing the metal sheet, of the at least one of the first viscoelastic layer or the second viscoelastic layer.

15. The electromagnetic shield of claim 1, wherein
at least one of the first viscoelastic layer or the second viscoelastic layer is gelatinous.

16. The electromagnetic shield of claim 1, wherein
at least one of the first viscoelastic layer or the second viscoelastic layer has an adhesive surface having a groove with a plurality of stripe portions, the adhesive surface being opposite from another surface, facing the metal sheet, of the at least one of the first viscoelastic layer or the second viscoelastic layer,
the plurality of stripe portions being arranged side by side in a direction different from a direction in which the plurality of stripe portions extend.

17. A communications unit comprising:
the electromagnetic shield of claim 1; and
a communications device,
the communications device including:
a housing to be adhered onto the first viscoelastic layer;
a terminal block held by the housing and configured to allow a cable to be connected to the terminal block; and
a communications module held by the housing and configured to wirelessly output data that the communications module has received via the cable.

18. The communications unit of claim 17, wherein
the housing includes a bumper.

19. The communications unit of claim 17, wherein
the communications device further includes:
a light source housed in the housing; and
a light guide member housed in the housing and configured to guide light emitted from the light source.
